(19) United States
(12) Patent Application Publication
(10) Pub. No.: US 2005/0061539 A1
(43) Pub. Date: Mar. 24, 2005

(54) Mechanism for disabling an electronic assembly

(76) Inventor: Russell Norman Mirov, Los Altos, CA (US)

Correspondence Address: PARK, VAUGHAN & FLEMING LLP, 702 MARSHALL STREET, SUITE 310, REDWOOD CITY, CA, 94063, US

(21) Appl. No.: 10/667,115

(22) Filed: Sep. 19, 2003

(51) Int. Cl. H05K 7/06

(52) U.S. Cl. 174/250

(57) ABSTRACT

A mechanism for provably disabling an electronic assembly such as a circuit board. The mechanism comprises a tab or key, normally attached to the assembly during operation, but which, when detached, prevents the assembly from being fully functional. The key may comprise a portion of the assembly. The key comprises a wire trace or other signal conductor that is severed when the key is detached from the assembly. The assembly may fail to power up if the conductor is broken, or a processing element on the assembly may detect the broken conductor and disable some or all functionality of the assembly. The key may also include an identification that can be used as evidence of the key removal.

### BACKGROUND

This invention relates to the field of electronics. More particularly, a mechanism is provided for disabling an electronic assembly or component.

Manufacturers and vendors of electronic assemblies (e.g., computer motherboards, circuit boards) often wish to dispose of an assembly if it is broken or defective in some manner, is obsolete or is otherwise no longer usable or otherwise needed. Manufacturers often contract with third parties for disposal of such assemblies.

However, it is not uncommon for assemblies that a manufacturer or vendor releases for disposal to end up back in circulation. For example, an assembly previously sent for disposal may be returned to its manufacturer as defective, in the hope of receiving a refund, or may be presented to a vendor as a functional item. The manufacturer or vendor may thus end up paying for the fraudulent or accidental failure to properly dispose of the assembly.

Thus, what is needed is a mechanism or manner of disabling an electronic assembly or component so that its destruction can be assured and/or it cannot be passed off as a functional unit.

### SUMMARY

In one embodiment of the invention, a mechanism is provided for provably disabling an electronic assembly such as a circuit board. In this embodiment, the mechanism comprises a tab or key that is normally attached to the assembly during operation. The key may comprise a portion of the assembly itself. If and when the key is detached, the assembly is prevented from being fully functional.

In this embodiment, the key also comprises a wire trace, optical conduit or other signal conductor that is severed or altered when the key is detached from the assembly. The assembly may fail to power up if the conductor is altered (e.g., broken). Or, a processing element on the assembly may detect the broken conductor and disable some or all functionality of the assembly or simply report the absence of the key.

In an embodiment of the invention, the key may include some form of identification. The identification may comprise a hologram, a barcode, a serial number or other sequence of alphanumeric characters, an electronic identification chip, etc.

Removal of the key and proper disposal of the assembly may be evidenced by the detached key or through manual or automated visual inspection of the assembly.

### DESCRIPTION OF THE FIGURES

FIG. 1 is a block diagram depicting a mechanism for disabling an electronic assembly, in accordance with one embodiment of the present invention.

FIG. 2 is a block diagram of a mechanism for provably disabling an electronic assembly, in accordance with one embodiment of the invention.

FIG. 3 depicts another mechanism for disabling an electronic assembly, in accordance with another embodiment of the present invention.

FIG. 4 depicts yet another mechanism for disabling an electronic assembly, in accordance with another embodiment of the present invention.

### DETAILED DESCRIPTION

The following description is presented to enable any person skilled in the art to make and use the invention, and is provided in the context of particular applications of the invention and their requirements. Various modifications to the disclosed embodiments will be readily apparent to those skilled in the art and the general principles defined herein may be applied to other embodiments and applications without departing from the scope of the present invention. Thus, the present invention is not intended to be limited to the embodiments shown, but is to be accorded the widest scope consistent with the principles and features disclosed herein.

In one embodiment of the invention, a mechanism is provided for ensuring an electronic assembly is disabled. The mechanism may be used in a method of proving an assembly has been disabled, or in a method of determining whether an assembly has been disabled. The electronic assembly may be a circuit board, processor board or other assembly comprising electronic components, and may be designed for use in a computer or other electronic device.

In an embodiment of the invention, the mechanism comprises a portion of an electronic assembly that can be detached from the assembly. More particularly, the mechanism may comprise a tab or other protuberance. The mechanism also comprises a signal conduit (e.g., a wire trace) that is severed when the mechanism is detached. When the conduit is severed, the assembly becomes fully or partially non-functional. Illustratively, the signal conduit may be laid on an inner layer of a multi-layer assembly board. This may make it more difficult for a third party to manipulate the conduit.

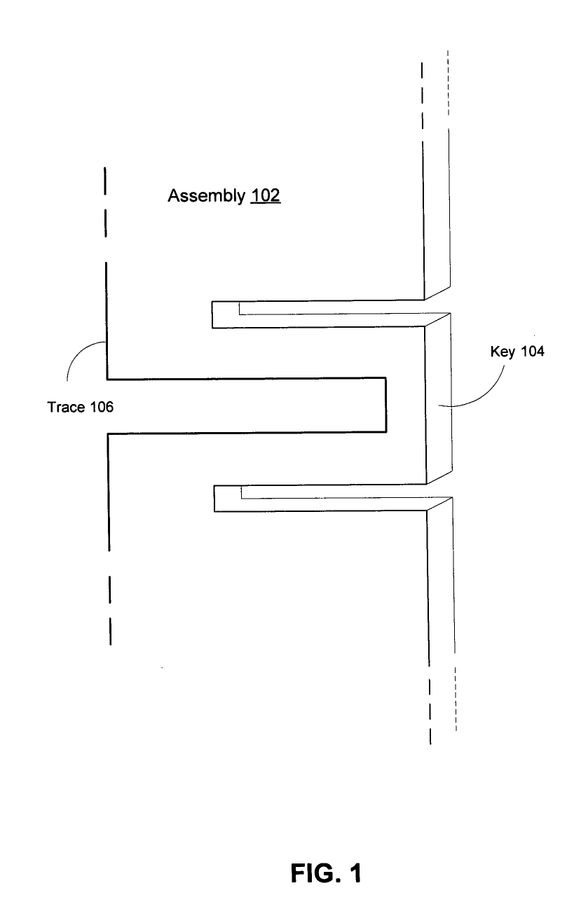

FIG. 1 is a block diagram of a mechanism for disabling an electronic assembly, according to one embodiment of the invention. Assembly 102 may be a motherboard or other assembly installable in a computer system. Assembly 102 comprises tab or key 104 and trace 106.

Trace 106 is coupled to a processor or other integrated circuit that is programmed to test whether the trace is intact, and/or make some or all operations of the assembly non-functional when the trace is broken. Alternatively, trace 106 could be part of a power circuit for the assembly. Trace 106 may be a metallic or optical signal conduit.

The dimensions and configuration (e.g., shape) of key 104 may vary greatly among different embodiments of the invention. For example, the thicker the assembly (e.g., the assembly substrate), the greater the surface area of the key may be to facilitate its removal.

In another embodiment of the invention, some form of identification may be included on a key, and may be used as evidence that the assembly was made non-functional. For example, the key may include a barcode, a hologram, an etched identification string, an electronic identification chip, etc. A company or other entity charge with disposing of an assembly that includes such a key may proffer the key as evidence of the assembly's proper disposal. Further, by matching key identifications of assemblies it receives against those sent for disposal, a manufacturer or vendor can determine if an assembly has been improperly recycled.

A key identification may be encapsulated (e.g., in epoxy) to make it difficult to remove without destroying the identification. Other forms of identification (e.g., a barcode, a hologram) may be configured to shred if an attempt is made to remove or tamper with them.

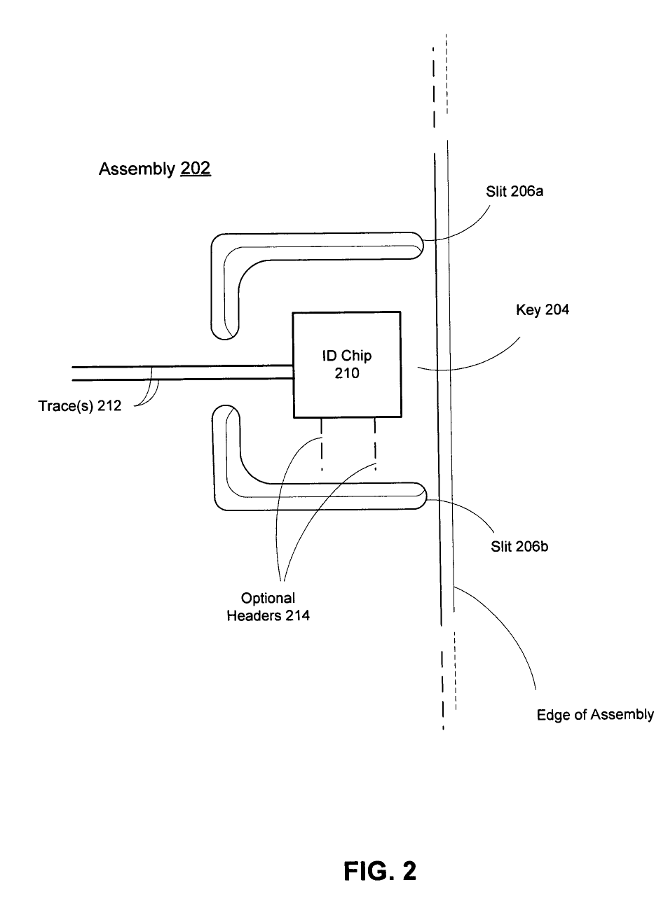

FIG. 2 is a block diagram of another mechanism for provably disabling an electronic assembly, according to one embodiment of the invention in which the mechanism includes an identification code.

In FIG. 2, assembly 202 includes key mechanism 204, which is partially defined by slits 206. The slits facilitate separation of the key from the assembly. In other embodiments of the invention, removal of the key may be facilitated by one or more slits, slots, gaps, channels, bores or other spaces aligned about the key, or between the key and the remainder of the electronic assembly. The spaces may be arranged in any configuration (e.g., horizontal, vertical, diagonal, irregular), and may be of any number. In another embodiment of the invention, separation of a key from an assembly may be facilitated by weakened or thinner substrate at a boundary of the key (i.e., instead of, or in addition to, a gap).

Key 204 may be composed partially or fully of the same material as the assembly, or of different material.

Although key 204 is situated at an internal or external edge of assembly 202, it could be located at a distance from an edge, could be aligned at an angle to the main surface of the assembly, or in some other orientation. In other words, key 204 is shown being coplanar with assembly 202 in FIG. 2. However, in other embodiments of the invention, they need not be coplanar.

Key 204 includes ID chip 210, on which an identification number or code is permanently encoded or programmed. Chip 210 may comprise a preprogrammed identification module (e.g., a PROM or EPROM) offered by Dallas Semiconductor, Maxim Integrated Products or some other manufacturer. ID chip 210 may be encapsulated to prevent its removal and installation on a different assembly. Illustratively, the identification code may be unique and complex (e.g., long), and may be laser encoded, to prevent it from being easily cloned.

Trace(s) 212 lead to/from key 204 and/or ID chip 210. If a trace 212 is broken, assembly 202 becomes partly or fully non-functional.

Optional headers 214 allow the identification to be read on-line and/or off-line, so that the identification code may be readable after key 204 is detached from the assembly. In one embodiment of the invention, the identification can only be read after the key is detached from the assembly (e.g., after trace 212 is broken). An entity charged with destroying assembly 202 could demonstrate its proper disposal by reading and reporting the identification code from the chip. Headers 214 may comprise virtually any form of signal connector, such as edge finger pads, header posts, etc.

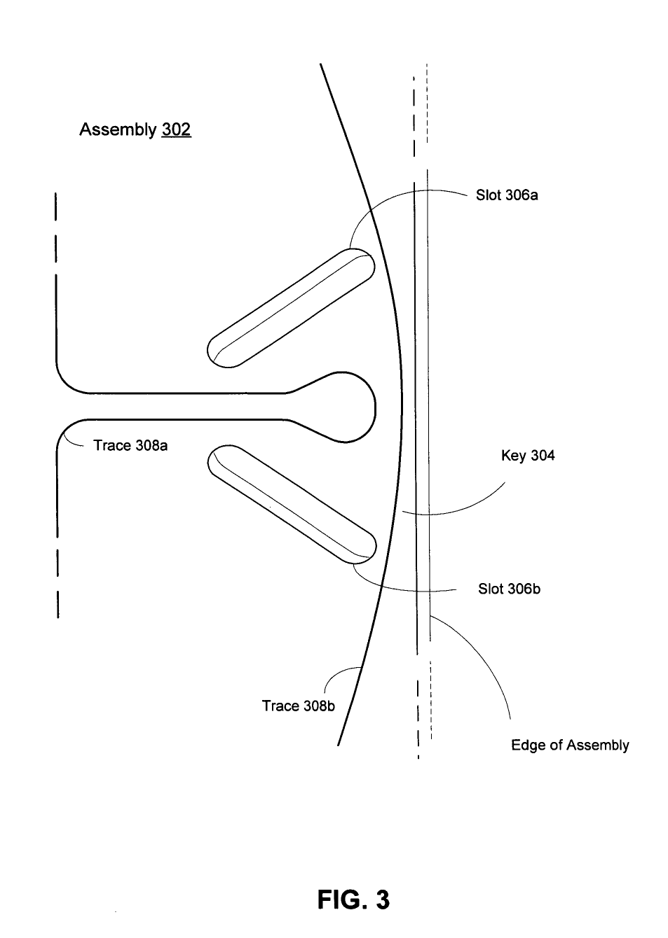

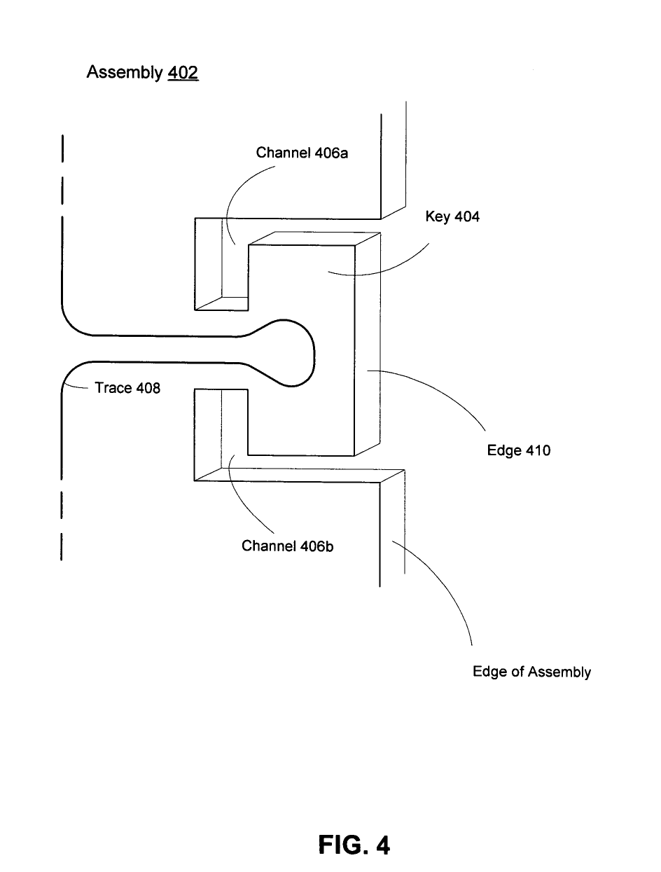

FIGS. 3-4 demonstrate alternative configurations of a mechanism for disabling an electronic assembly, according to other embodiments of the invention.

In FIG. 3, one or more slots 306 are arranged to facilitate detachment of key 304 from assembly 302. The slots may be of any dimensions. Traces 308a, 308b demonstrate different possible configurations of a trace for disabling the assembly when the key is detached. Either or both of them, and/or others, may be employed.

In FIG. 4, key 404 is defined by channels 406 in assembly 402. Edge 410 may be offset from an internal or external edge of the assembly, or may be flush with the assembly edge. In this and other embodiments, corners or edges of the key may be beveled to promote ease of handling and minimize the possibility of it catching or snagging on something.

In one embodiment of the invention, visual or optical inspection may be used to determine if a detachable key has been detached. Illustratively, an optical source or sensor may be configured to detect whether the key is in place.

The foregoing embodiments of the invention have been presented for purposes of illustration and description only. They are not intended to be exhaustive or to limit the invention to the forms disclosed. Accordingly, the scope of the invention is defined by the appended claims, not the preceding disclosure.

1. A circuit board comprising a mechanism for provably disabling the circuit board, the mechanism comprising:
signal means for conducting a signal between the mechanism and the circuit board; and
separation means for facilitating detachment of the mechanism from the circuit board;
wherein the circuit board becomes at least partly non-functional if the mechanism is detached from the circuit board.

2. The circuit board of claim 1, wherein said signal means comprises a wire trace.

3. The circuit board of claim 1, wherein said separation means comprises one or more gaps between the mechanism and the circuit board.

4. The circuit board of claim 1, wherein the mechanism further comprises:
identification means for identifying the mechanism.

5. The circuit board of claim 4, wherein said identification means comprises an identification circuit.

6. The circuit board of claim 4, wherein said identification means comprises a visible identification code.

7. The circuit board of claim 4, wherein said identification means is protected from being easily manipulated.

8. In an electronic assembly, a mechanism for at least partially disabling the electronic assembly, the mechanism comprising:
a segment of the electronic assembly configured to be detachable from the electronic assembly;
one or more signal conductors configured to carry one or more signals between the mechanism and the electronic assembly; and
an identification;
wherein said signal conductor is broken when said segment is detached from the electronic assembly.

9. The mechanism of claim 8, wherein said identification comprises an electronic identification module having a programmed identification code.

10. The mechanism of claim 9, wherein said identification code is readable only after said one or more signal conductors are severed.

11. The mechanism of claim 8, wherein said identification is protected from being manipulated.

12. The mechanism of claim 8, wherein said identification is encapsulated to prevent easy removal of said identification.

13. The mechanism of claim 8, wherein the mechanism is bordered by one or more gaps separating the mechanism from the electronic assembly.

14. The mechanism of claim 8, wherein the electronic assembly is a circuit board, and said segment comprises a segment of the circuit board bordering an edge of the circuit board.

15. The mechanism of claim 14, wherein the edge of the circuit board is an external edge of the circuit board.

16. The mechanism of claim 14, wherein the edge of the circuit board is an internal edge defined by a bore through the circuit board.

17. A mechanism for disabling an electronic assembly, comprising:
a portion of the electronic assembly detachable from the assembly; and
within said portion, a signal conduit configured to carry a signal;
wherein the electronic assembly is operable while said portion is attached to the assembly; and
wherein one or more functions of the electronic assembly become inoperable when said portion is detached from the assembly.

18. The mechanism of claim 17, further comprising an identification module.

19. The mechanism of claim 18, wherein said identification module is configured to prevent manipulation of said identification module.

20. The mechanism of claim 18, wherein said identification module comprises a programmed identification code.

21. The mechanism of claim 18, wherein said identification module comprises a barcode.

22. The mechanism of claim 18, wherein said identification module comprises a hologram.

23. The mechanism of claim 18, wherein said identification module comprises a serial number.

24. The mechanism of claim 17, wherein said portion and the assembly are coplanar.

25. The mechanism of claim 17, wherein the mechanism further comprises one or more gaps between said portion and the assembly.

26. The mechanism of claim 17, wherein a plane of said portion is aligned at an angle to a plane of the assembly during normal operation of the electronic assembly.

27. A method of ensuring the disablement of an electronic assembly, comprising:
receiving an electronic assembly for disablement, the electronic assembly comprising a detachable key, said key comprising:
a signal conductor configured to convey a signal between said key and the electronic assembly;
detaching said key from the electronic assembly; and
proffering evidence that said key has been detached.

28. The method of claim 27, wherein said proffering comprises proffering said key.

29. The method of claim 27, wherein said key further comprises:
an identification code.

30. The method of claim 29, wherein said proffering comprises proffering said identification code.

31. The method of claim 29, wherein said identification code is one of: a barcode, a serial number and a hologram.

32. The method of claim 29, wherein said identification code is a code programmed into an electronic identification module.

33. The method of claim 27, wherein said detaching comprises:
severing said signal conductor.
